(19) United States
(12) Patent Application Publication
(10) Pub. No.: US 2026/0092991 A1
(43) Pub. Date: Apr. 2, 2026

(54) MAGNETIC SENSOR AND MAGNETIC FIELD IDENTIFICATION METHOD

(71) Applicant: Asahi Kasei Microdevices Corporation, Tokyo (JP)

(72) Inventor: Tomohiro YOSHIOKA, Tokyo (JP)

(21) Appl. No.: 19/339,220

(22) Filed: Sep. 24, 2025

(30) Foreign Application Priority Data
Sep. 27, 2024 (JP) 2024-168131

(51) Int. Cl. G01R 33/02; G01R 33/00; G01R 33/07

(52) U.S. Cl. CPC G01R 33/0206; G01R 33/0011; G01R 33/0029; G01R 33/0094; G01R 33/072

(57) ABSTRACT

Provided is a magnetic sensor to identify three components of X, Y, and Z of an incident magnetic field in a three-dimensional Cartesian coordinate system. The magnetic sensor comprises a pair of first magnetoelectric conversion elements positioned in a first quadrant and a third quadrant and a pair of second magnetoelectric conversion elements positioned in a second quadrant and a fourth quadrant, wherein the pair of first magnetoelectric conversion elements have a magnetosensitive axis along a first axis obtained by rotating the X-axis by 45 degrees, the pair of second magnetoelectric conversion elements have a magnetosensitive axis along a second axis orthogonal to the first axis, ,and an area of an imaginary rectangle formed by connecting the points proximate to each other in the pair of first magnetoelectric conversion elements and in the pair of second magnetoelectric conversion elements is smaller than an area of the magnetoelectric conversion element.

The contents of the following patent application(s) are incorporated herein by reference:

NO. 2024-168131 filed in JP on September 27, 2024.

### BACKGROUND

### 1. TECHNICAL FIELD

The present invention relates to a magnetic sensor and a magnetic field identification method.

### 2. RELATED ART

Patent document 1 describes that "the sensor elements 211 and 212 can detect not only the signal based on the Z-axis component of the magnetic field, but also the signal based on the X-axis component; and the sensor elements 213 and 214 can detect not only the signal based on the Z-axis component of the magnetic field, but also the signal based on the Y-axis component simultaneously" (in paragraph 0080). Patent document 2 describes that "using the groups of Hall sensors, three dimensional positional information of the magnetic module is detected, thereby enabling an angle formed between a first body which includes a sensor unit and a second body which includes a magnetic module to be measured" (paragraph 0012).

### RELATED ART DOCUMENTS

### Patent document

Patent Document 1: Japanese Patent No. 4939540

Patent Document 2: Japanese Patent No. 6151301

### BRIEF DESCRIPTION OF THE DRAWINGS

FIG. 1 is a block diagram showing a schematic configuration of a magnetic field identification device 10 according to one embodiment.

FIG. 2 is a plan view schematically showing an example configuration of a magnetic sensor 100 according to one embodiment.

FIG. 3 is a plan view illustrating an arrangement and the like of a magnetoelectric conversion elements 101 and the like in the magnetic sensor 100 according to one embodiment.

FIG. 4 is a plan view illustrating an arrangement of the magnetoelectric conversion elements 101 and the like in the magnetic sensor 100 according to one embodiment.

FIG. 5 is a plan view illustrating an arrangement of the magnetoelectric conversion elements 101 and the like in the magnetic sensor 100 according to one embodiment.

FIG. 6 is a cross-sectional view illustrating an incident magnetic field that is incident on a cross section along a line L-L' in FIG. 2.

### DESCRIPTION OF EXEMPLARY EMBODIMENTS

The present invention will be described below through embodiments of the invention, but the following embodiments do not limit the invention according to the claims. In addition, not all combinations of features described in the embodiments are essential to a solution of the invention.

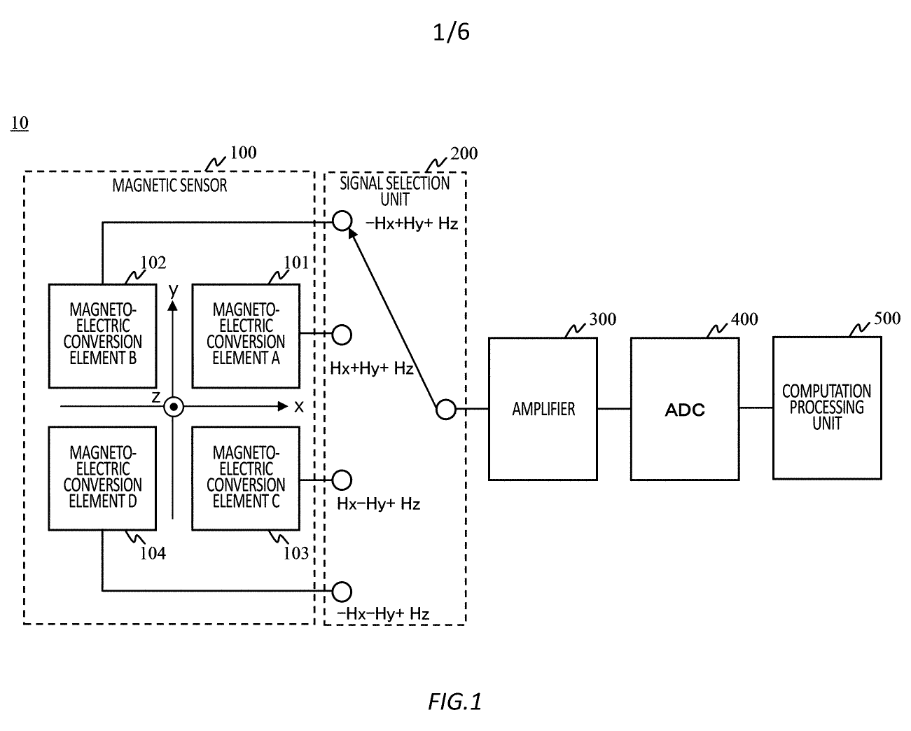

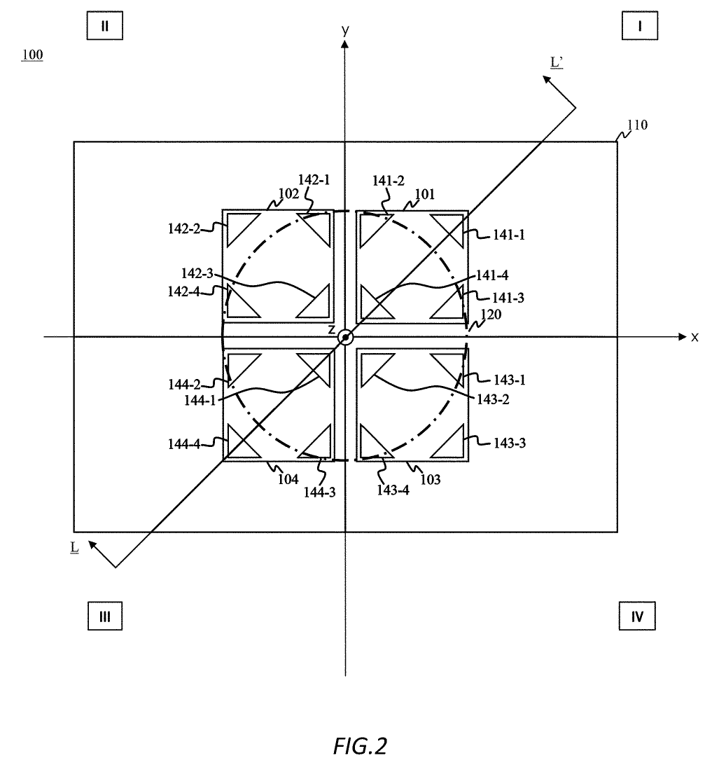

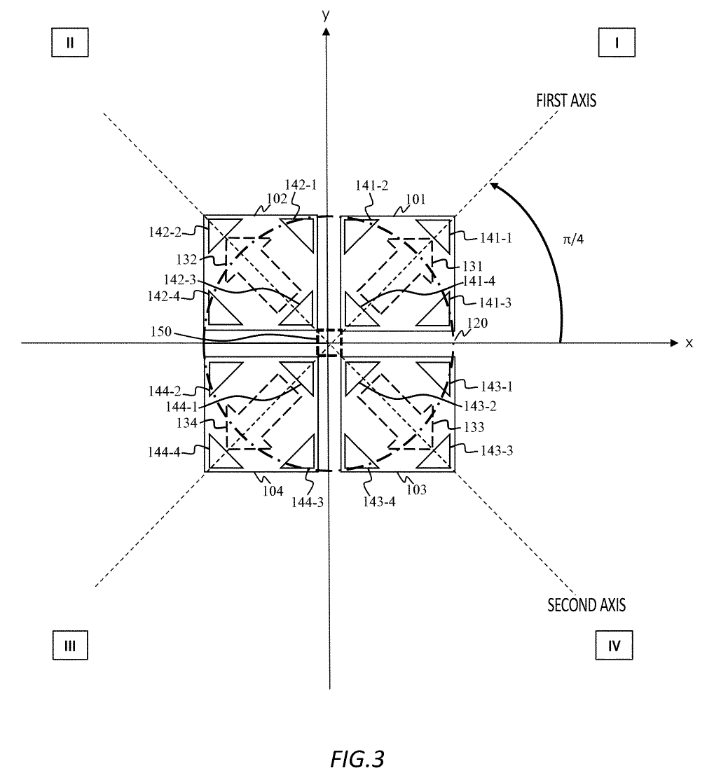

FIG. 1 is a block diagram showing a schematic configuration of the magnetic field identification device 10 according to one embodiment. FIG. 2 is a plan view schematically showing an example configuration of the magnetic sensor 100 according to one embodiment. FIG. 3 is a plan view illustrating an arrangement and the like of the magnetoelectric conversion elements 101 and the like in the magnetic sensor 100 according to one embodiment.

The magnetic field identification device 10 is a device that identifies three components of X, Y, and Z of the incident magnetic field in a three-dimensional Cartesian coordinate system. The magnetic field identification device 10 includes the magnetic sensor 100, a signal selection unit 200, an amplifier 300, an ADC 400, and a computation processing unit 500. The magnetic field identification device 10 is incorporated in a portable device, for example.

The magnetic sensor 100 is a sensor to identify the three components described above. The magnetic sensor 100 includes a plurality of magnetoelectric conversion elements 101, 102, 103, and 104 to detect the incident magnetic field. The magnetic sensor 100 of the present embodiment further includes a silicon substrate 110 and a magnetic flux concentrator 120 as shown in FIG. 2. Note that the three-dimensional Cartesian coordinate system described above is defined, for example, in accordance with an atomic arrangement direction of the silicon substrate 110, but is not limited thereto. When a direction perpendicular to a wafer surface of the silicon substrate 110 is defined as the Z-axis, the X and Y directions may be arbitrarily determined as two orthogonal axes in the plane orthogonal to the Z-axis.

As shown in FIG. 2, when four quadrants I to IV formed of the X-axis, the Y-axis, and the intersection point of the X-axis and the Y-axis are defined, the magnetic sensor 100 includes a pair of magnetoelectric conversion elements 101, 104 positioned in the first quadrant I and the third quadrant III and a pair of magnetoelectric conversion elements 102, 103 positioned in the second quadrant II and the fourth quadrant IV. The pair of magnetoelectric conversion elements 101, 104 is an example of a pair of first magnetoelectric conversion elements, and the pair of magnetoelectric conversion elements 102, 103 is an example of a pair of second magnetoelectric conversion elements. The four magnetoelectric conversion elements 101 and the like are formed on the silicon substrate 110. Note that the magnetoelectric conversion elements 101 and the like may be referred to as a Hall element in the following description. Note that the four quadrants I to IV are similarly shown in the plan views of FIG. 2 and thereafter, and redundant descriptions are omitted.

Each of the pair of magnetoelectric conversion elements 101, 104 has a magnetosensitive axis along the first axis obtained by rotating the X-axis or the Y-axis by 45 degrees (π/4). The pair of magnetoelectric conversion elements 101, 104 are arranged so that the positive directions of their magnetosensitive axes are opposite to each other. More specifically, with respect to the first axis obtained by rotating the X-axis by 45 degrees as indicated by a fine dashed line in FIG. 3, the magnetoelectric conversion element 101 has a magnetosensitive axis 131 along the first axis, and the magnetoelectric conversion element 104 has a magnetosensitive axis 134 along the first axis. In FIG. 3, the magnetosensitive axes 131, 134 are shown by an arrow of a coarse dashed line. The magnetosensitive axis 131 is the axis obtained by rotating the X-axis by 45 degrees, and the magnetosensitive axis 134 is the axis obtained by rotating the X-axis by 225 degrees. Note that, as will be described below in detail, the magnetosensitive axes 131 and the like of the magnetoelectric conversion elements 101 and the like are determined based on the relative position of the magnetoelectric conversion elements 101 and the like relative to the magnetic flux concentrator 120 indicated by a dash-dot line in FIGS. 2 and 3.

At least one of the pair of magnetoelectric conversion elements 101, 104 has an electrode pair arranged along the first axis. More specifically, as shown in FIGS. 2 and 3, the magnetoelectric conversion element 101 has a pair of electrodes 141-1, 141-4 and a pair of electrodes 141-2, 141-3, and the pair of electrodes 141-1, 141-4 are arranged along the first axis. The pair of electrodes 141-2, 141-3 are arranged along an axis that intersects the first axis. In other words, in the X-Y plane, the magnetoelectric conversion element 101 has two sets of electrode pairs, and the two sets of electrode pairs are arranged so that a line connecting one electrode pair with each other intersects a line connecting another electrode pair with each other. As an example, as shown in FIG. 2, the pair of electrodes 141-2, 141-3 may be arranged along a second axis to be described below, i.e., they may be arranged so that a line connecting the pair of electrodes 141-1, 141-4 with each other is orthogonal to a line connecting the pair of electrodes 141-2, 141-3 with each other. Note that the profile of the electrode 141-1 and the like in the X-Y plane may be a triangular shape as illustrated in FIGS. 2 and 3 or may be a shape other than the triangular shape, and the same applies to electrodes of other magnetoelectric conversion elements 104 and the like, and redundant descriptions are omitted.

Similarly, the magnetoelectric conversion element 104 has a pair of electrodes 144-1, 144-4 and a pair of electrodes 144-2, 144-3, and the pair of electrodes 144-1, 144-4 are arranged along the first axis. The pair of electrodes 144-2, 144-3 are arranged along an axis that intersects the first axis. In other words, in the X-Y plane, the magnetoelectric conversion element 104 has two sets of electrode pairs, and the two sets of electrode pairs are arranged so that a line connecting one electrode pair with each other intersects a line connecting another electrode pair with each other. As an example, as shown in FIG. 2, the pair of electrodes 144-2, 144-3 may be arranged along the second axis to be described below, i.e., they may be arranged so that a line connecting the pair of electrodes 144-1, 144-4 with each other is orthogonal to a line connecting the pair of electrodes 144-2, 144-3 with each other.

Meanwhile, each of the pair of magnetoelectric conversion elements 102, 103 has a magnetosensitive axis along the second axis which is orthogonal to the first axis. The pair of magnetoelectric conversion elements 102, 103 are arranged so that the positive directions of their magnetosensitive axes are opposite to each other. More specifically, with respect to the second axis which is orthogonal to the first axis as indicated by a fine dashed line in FIG. 3, the magnetoelectric conversion element 102 has a magnetosensitive axis 132 along the second axis, and the magnetoelectric conversion element 103 has a magnetosensitive axis 133 along the second axis. In FIG. 3, the magnetosensitive axes 132, 133 are shown by an arrow of a coarse dashed line. The magnetosensitive axis 132 is the axis obtained by rotating the X-axis by 135 degrees, and the magnetosensitive axis 133 is the axis obtained by rotating the X-axis by 315 degrees.

At least one of the pair of magnetoelectric conversion elements 102, 103 has an electrode pair arranged along the second axis. More specifically, as shown in FIGS. 2 and 3, the magnetoelectric conversion element 102 has a pair of electrodes 142-1, 142-4 and a pair of electrodes 142-2, 142-3, and the pair of electrodes 142-2, 142-3 are arranged along the second axis. The pair of electrodes 142-1, 142-4 are arranged along an axis that intersects the second axis. In other words, in the X-Y plane, the magnetoelectric conversion element 102 has two sets of electrode pairs, and the two sets of electrode pairs are arranged so that a line connecting one electrode pair with each other intersects a line connecting another electrode pair with each other. As an example, the pair of electrodes 142-1, 142-4 may be arranged along the first axis, i.e.,, they may be arranged so that a line connecting the pair of electrodes 142-1, 142-4 with each other is orthogonal to a line connecting the pair of electrodes 142-2, 142-3 with each other.

Similarly, the magnetoelectric conversion element 103 has a pair of electrodes 143-1, 143-4 and a pair of electrodes 143-2, 143-3, and the pair of electrodes 143-2, 143-3 are arranged along the second axis. The pair of electrodes 143-1, 143-4 are arranged along an axis that intersects the second axis. In other words, in the X-Y plane, the magnetoelectric conversion element 103 has two sets of electrode pairs, and the two sets of electrode pairs are arranged so that a line connecting one electrode pair with each other intersects a line connecting another electrode pair with each other. As an example, the pair of electrodes 143-1, 143-4 may be arranged along the first axis, i.e., they may be arranged so that a line connecting the pair of electrodes 143-1, 143-4 with each other is orthogonal to a line connecting the pair of electrodes 143-2, 143-3 with each other.

A rectangle 150 indicated by a coarse and bold dashed line in FIG. 3 is an example of an imaginary rectangle formed by connecting with each other a pair of points that are proximate to each other in the pair of magnetoelectric conversion elements 101, 104 and a pair of points that are proximate to each other in the pair of magnetoelectric conversion elements 102, 103 in the X-Y plane. The rectangle 150 can also be described as an imaginary rectangle formed by connecting with each other the points of the respective magnetoelectric conversion elements 101 and the like which are closest to the point of origin in a sequential order of the magnetoelectric conversion elements 101, 102, 104, and 103. In the magnetic sensor 100, the area of the rectangle 150 in the X-Y plane is smaller than an area of each of the four magnetoelectric conversion elements 101 and the like. In other words, the four magnetoelectric conversion elements 101 and the like are formed in proximity to each other on the silicon substrate 110 so that the area of the rectangle 150 becomes smaller than the area of each of the four magnetoelectric conversion elements 101 and the like.

As described above, the magnetic sensor 100 to identify the three components of X, Y, and Z of the incident magnetic field in the three-dimensional Cartesian coordinate system includes the pair of magnetoelectric conversion elements 101, 104 positioned in the first quadrant I and the third quadrant III and the pair of magnetoelectric conversion elements 102, 103 positioned in the second quadrant II and the fourth quadrant IV. The pair of magnetoelectric conversion elements 101, 104 each have the magnetosensitive axes along the first axis obtained by rotating the X-axis or the Y-axis by 45 degrees (π/4), and are arranged so that the positive directions of their magnetosensitive axes are opposite to each other. At least one of the pair of magnetoelectric conversion elements 101, 104 has an electrode pair arranged along the first axis. Meanwhile, the pair of magnetoelectric conversion elements 102, 103 each have the magnetosensitive axes along the second axis which is orthogonal to the first axis, and are arranged so that the positive directions of their magnetosensitive axes are opposite to each other.

Here, as a comparative example of the magnetic sensor 100 including such a configuration, a magnetic sensor is assumed that includes a pair of magnetoelectric conversion elements arranged on the X-axis so that the positive directions of their magnetosensitive axes are opposite to each other along the X-axis and an another pair of magnetoelectric conversion elements arranged on the Y-axis so that the positive directions of their magnetosensitive axes are opposite to each other along the Y-axis. In order for the magnetic sensor to identify the three components of XYZ of the incident magnetic field, the pair of magnetoelectric conversion elements need to have respective centers of gravity arranged at an equal distance from the intersection point of the two axes of X and Y, i.e., from the point of origin in the X-Y plane, as well as the another pair of magnetoelectric conversion elements also need to have respective centers of gravity arranged at an equal distance from the point of origin in the X-Y plane.

In the magnetic sensor of the comparative example, when an attempt is made to reduce an area occupied by an imaginary square that circumscribes four magnetoelectric conversion elements in the X-Y plane by arranging the four magnetoelectric conversion elements closer to the point of origin in the X-Y plane, the width occupied by the magnetoelectric conversion element pair arranged on one of the X-axis or the Y-axis falls within approximately twice the element width. However, the width occupied by the magnetoelectric conversion element pair arranged on another of the X-axis or the Y-axis becomes approximately three times the element width due to the presence of the magnetoelectric conversion element pair arranged on the one of the X-axis or the Y-axis between the magnetoelectric conversion element pair in question. Accordingly, in the magnetic sensor of the comparative example, the width occupied by the magnetoelectric conversion element cannot be reduced to or less than three times the element width in at least one of the X-axis or the Y-axis, and thus the occupied area described above cannot be sufficiently reduced.

In contrast, according to the magnetic sensor 100 of the present embodiment, the above-described configuration enables the pair of magnetoelectric conversion elements 101, 104 to be arranged in proximity along the first axis described above as well as enables the pair of magnetoelectric conversion element 102, 103 to be arranged in proximity along the second axis described above without any dead space created around the point of origin, thereby also allowing the area occupied by the imaginary square in the X-Y plane circumscribing the four magnetoelectric conversion elements 101 and the like to be minimized. Note that, according to the magnetic sensor 100 with the above-described configuration, in order to meet design specifications, the pair of magnetoelectric conversion elements 101, 104 can be arranged apart from each other along the first axis as well as the pair of magnetoelectric conversion elements 102, 103 can be arranged apart from each other along the second axis, i.e., the degree of freedom in the layout of the four magnetoelectric conversion elements can be increased.

As described above, since the area of the rectangle 150 in the X-Y plane is smaller than the area of each of the four magnetoelectric conversion elements 101 and the like, the magnetic sensor 100 of the present embodiment can further reduce the occupied area described above sufficiently compared to the magnetic sensor of the comparative example, allowing the magnetic sensor 100 to be miniaturized. The magnetic field identification device 10 including the magnetic sensor 100 is incorporated in a portable device or the like as described above, and according to the magnetic sensor 100, it is possible to meet the increasing demand for miniaturization of magnetic sensors driven by the demand for multifunctionality or miniaturization of portable devices. Also, with the four magnetoelectric conversion elements 101 and the like closely arranged with each other in this manner, the magnetic sensor 100 can improve accuracy to identify the three components of XYZ of the incident magnetic field.

Hereinafter, the four magnetoelectric conversion elements 101 and the like in the magnetic sensor 100 of the present embodiment will be further described in detail. As an example, the magnetoelectric conversion elements 101 and the like of the present embodiment have a rectangular profile in the X-Y plane as shown in FIGS. 2 and 3. More specifically, each of the four magnetoelectric conversion elements 101 and the like has a rectangular profile with its diagonal lines along the first axis and the second axis in the X-Y plane as described above. Also, the rectangular profile of the magnetoelectric conversion elements 101 and the like has a pair of two opposing sides along the X-axis and another pair of two opposing sides along the Y-axis in the X-Y plane. Note that, in the X-Y plane, the magnetoelectric conversion elements 101 and the like may have a profile other than a rectangle, for example a cross-shaped profile in which portions without the four electrodes 141-1 and the like arranged are recessed.

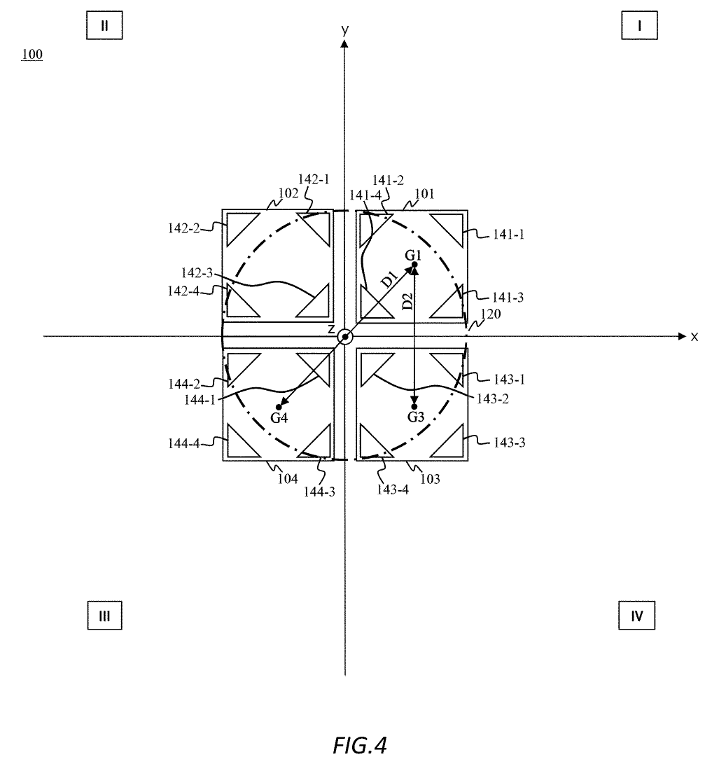

FIG. 4 is a plan view illustrating an arrangement of the magnetoelectric conversion elements 101 and the like in the magnetic sensor 100 according to one embodiment. In FIG. 4, the centers of gravity G1, G3, G4 of the magnetoelectric conversion elements 101, 103, 104 in the X-Y plane are shown by points colored in black, a distance D1 between the center of gravity G1 of the magnetoelectric conversion element 101 and the center of gravity G4 of the magnetoelectric conversion element 104 is shown by an arrow, and a distance D2 between the center of gravity G1 of the magnetoelectric conversion element 101 and the center of gravity G3 of the magnetoelectric conversion element 103 is shown by an arrow.

According to the magnetic sensor 100 of one embodiment, in the X-Y plane, the distance between the center of gravity of one of the pair of magnetoelectric conversion elements 101, 104 and the center of gravity of one of the pair of magnetoelectric conversion elements 102, 103 is shorter than the distance between the respective centers of gravity of the pair of magnetoelectric conversion elements 101, 104. More specifically, as shown in FIG. 4, the distance D2 between G1 and G3 is shorter than the distance D1 between G1 and G4, for example.

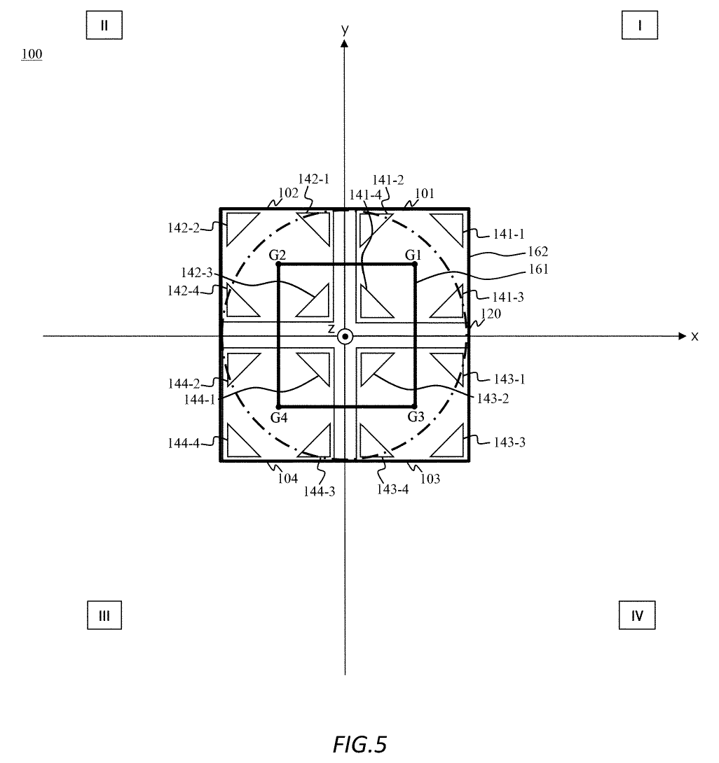

FIG. 5 is a plan view illustrating an arrangement of the magnetoelectric conversion elements 101 and the like in the magnetic sensor 100 according to one embodiment. In FIG. 5, the centers of gravity G1, G2, G3, G4 of the magnetoelectric conversion elements 101, 102, 103, 104 in the X-Y plane are shown by points colored in black, an imaginary first square 161 formed by connecting the centers of gravity G1 and the like of the four magnetoelectric conversion elements 101 and the like with each other is shown by a thick solid line, and an imaginary second square 162 circumscribing the four magnetoelectric conversion elements 101 and the like is shown by a thick solid line.

According to the magnetic sensor 100 of one embodiment, as shown in FIG. 5, the first square 161 described above and the second square 162 described above are in a similar relationship in the X-Y plane.

The magnetic flux concentrator 120 included in the magnetic sensor 100 of the present embodiment is arranged so that it overlaps with the four magnetoelectric conversion elements 101 and the like as shown by a dash-dot line in FIGS. 2 to 5. Specifically, the magnetic flux concentrator 120 is arranged to overlap with the four magnetoelectric conversion elements 101 and the like on the positive side of the Z-axis so that the outer edge portion of the magnetic flux concentrator 120 is positioned on the positive side of the Z-axis of the four magnetoelectric conversion elements 101 and the like.

More specifically, as shown in FIGS. 2 to 5, the magnetic flux concentrator 120 is arranged so that the outer edge portion of the magnetic flux concentrator 120 traverses above, i.e., on the positive side of the Z-axis of, one electrode pair of the two sets of electrode pairs included in each of the four magnetoelectric conversion elements 101 and the like in the X-Y plane. Also, as shown in FIG. 5, the magnetic flux concentrator 120 is arranged so that it has the outer edge portion inside the second square 162 described above in the X-Y plane. Also, as shown in FIG. 5, the magnetic flux concentrator 120 is arranged so that it has the outer edge portion outside the first square 161 described above in the X-Y plane.

In the magnetic sensor 100, in the X-Y plane, the area of a portion of the magnetic flux concentrator 120 which overlaps with the four magnetoelectric conversion elements 101 and the like is larger than the area of a portion of the magnetic flux concentrator 120 which does not overlap with the four magnetoelectric conversion elements 101 and the like. According to such a magnetic sensor 100, the occupied area described above can be sufficiently reduced compared to the magnetic sensor of the comparative example described above, and thus the magnetic sensor 100 can be miniaturized.

The magnetic flux concentrator 120 is made of a ferromagnetic material, which is a material having a high relative magnetic permeability. The profile of the magnetic flux concentrator 120 in the X-Y plane may be a circular shape as shown in FIGS. 2 to 5, or may be a shape other than the circular shape provided that the tangential line of the outer edge of the magnetic flux concentrator 120 is substantially parallel to the first axis or the second axis, i.e., provided that the magnetosensitive axes 131 and the like of the four magnetoelectric conversion elements 101 and the like are along the first axis or the second axis. The profile of the magnetic flux concentrator 120 in the X-Y plane may be an annular shape, or may be a polygonal shape such as a rectangular, rhombus, octagon, or dodecagon shape, for example. Also, thickness of the magnetic flux concentrator 120 in the Z-axis direction may be arbitrary, and also the thickness of the magnetic flux concentrator 120 in the Z-axis direction may be uniform in the X-Y plane or may vary between the outer edge portion and the center portion.

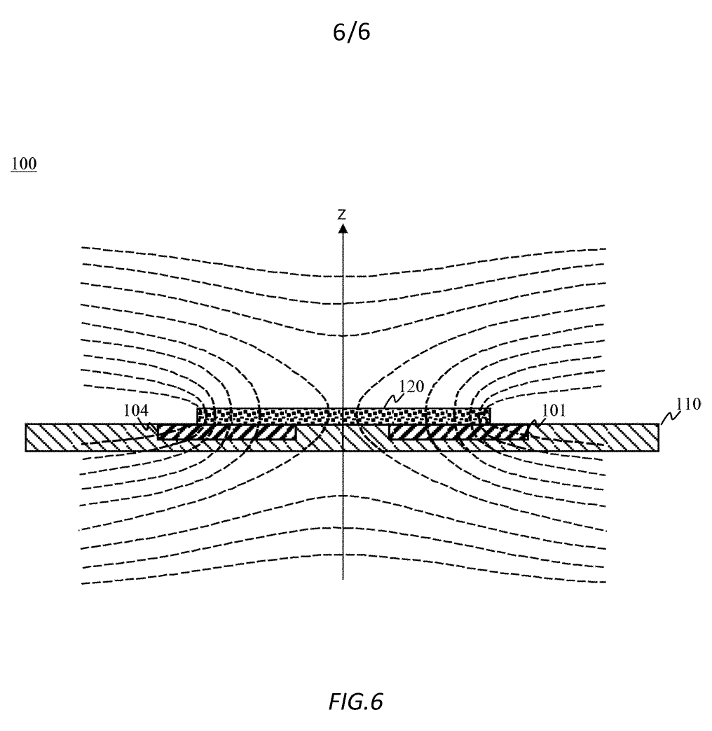

FIG. 6 is a cross-sectional view illustrating an incident magnetic field that is incident on a cross section along a line L-L' in FIG. 2. By the magnetic flux concentrator 120 made of the ferromagnetic material distorting the magnetic field, each of the four magnetoelectric conversion elements 101 and the like having the arrangement configuration described above is capable of detecting a signal that is detected based on the X-axis component and a signal that is detected based on the Y-axis component, in addition to a signal that is detected based on the Z-axis component of the incident magnetic field. More specifically, the four magnetoelectric conversion elements 101 and the like are sensitive to the magnetic component in the Z-axis direction (vertical direction), and as shown in FIGS. 2 to 5, they are arranged to be rotationally symmetric by 90 degrees relative to the point of origin so that they overlap with the edge of the circular magnetic flux concentrator 120 in the plan view. As shown by a plurality of dashed curves in FIG. 6, the magnetic flux in the X-axis direction and the Y-axis direction (horizontal direction) has the paths thereof bent in the course of being absorbed by the magnetic flux concentrator 120 and it comes to obtain a vertical component, and thus the four magnetoelectric conversion elements 101 and the like detect the magnetic flux in the vertical direction having the paths thereof being bent from the horizontal direction by the magnetic flux concentrator 120. Accordingly, the magnetic sensor 100 is capable of outputting, from the four magnetoelectric conversion elements 101 and the like, the signal that is proportional to the sum of the magnetic field strength in the vertical direction and the magnetic field strength in the horizontal direction. Note that as shown in FIG. 6, the four magnetoelectric conversion elements 101 and the like may be buried in the silicon substrate 110 with arbitrary thickness or may be formed on the silicon substrate 110 by a semiconductor process, and also as described above, the three-dimensional Cartesian coordinate system described above is defined, for example, in accordance with the atomic arrangement direction of the silicon substrate 110, but is not limited thereto. When a direction perpendicular to a wafer surface of the silicon substrate 110 is defined as the Z-axis, the X and Y directions may be arbitrarily determined as two orthogonal axes in the plane orthogonal to the Z-axis.

Further specifically, when a signal detected based on the X-component of the incident magnetic field is defined as Hx, a signal detected based on the Y-component is defined as Hy, and a signal detected based on the Z-component is defined as Hz, the four magnetoelectric conversion elements 101 and the like are arranged to detect Hx + Hy + Hz = A, - Hx + Hy + Hz = B, Hx - Hy + Hz = C, and - Hx - Hy + Hz = D. That is, as shown in FIG. 1, the magnetoelectric conversion element 101 is arranged to output the signal A = Hx + Hy + Hz, the magnetoelectric conversion element 102 is arranged to output the signal B = - Hx + Hy + Hz, the magnetoelectric conversion element 103 is arranged to output signal C = Hx - Hy + Hz, and the magnetoelectric conversion element 104 is arranged to output the signal D = -Hx - Hy + Hz. Since the magnetic sensor 100 is small in size, for example on the order of sub-millimeter or less, it may be considered that a uniform magnetic field is incident on the entire magnetic sensor 100. When the vertical component of the incident magnetic field is excluded, it may also be defined that the pair of magnetoelectric conversion element 101, 104 are arranged to magnetoelectrically convert the magnetic fields of + Hx + Hy and the magnetic field of - Hx - Hy, while the pair of magnetoelectric conversion elements 102, 103 are arranged to magnetoelectrically convert the magnetic field of - Hx + Hy and the magnetic field of + Hx - Hy.

In the magnetic field identification device 10, the signal selection unit 200 selectively outputs each of the signals A to D to the amplifier 300 by sequentially switching, in a time-division manner, the four signals of A to D output from the magnetic sensor 100. Specifically, the signal selection unit 200 connects the output terminal of the magnetoelectric conversion element 101 to the input terminal of the amplifier 300 to output the signal A to the amplifier 300, then connects the output terminal of the magnetoelectric conversion element 102 to the input terminal of the amplifier 300 to output the signal B to the amplifier 300, then connects the output terminal of the magnetoelectric conversion element 103 to the input terminal of the amplifier 300 to output the signal C to the amplifier 300, and then connects the output terminal of the magnetoelectric conversion element 104 to the input terminal of the amplifier 300 to output the signal D to the amplifier 300, and repeats this process. The amplifier 300 amplifies the signal input from the signal selection unit 200 and outputs it to the ADC 400, which is an analog-to-digital conversion circuit, and the ADC 400 converts the signal into digital data and outputs it to the computation processing unit 500.

In this manner, the computation processing unit 500 acquires the values of the four magnetic fields of A to D. Based on these four values of the magnetic fields, the computation processing unit 500 identifies Hx by Hx = {(A + C) - (B + D)}/4, identifies Hy by Hy = {(A + B) - (C + D)}/4, and identifies Hz by Hz = (A + B + C + D)/4. Once the values of signals Hx, Hy, Hz are identified, the computation processing unit 500 may determine the strength of the X-component, the Y-component, and the Z-component of the incident magnetic field corresponding to these values.

While the present invention has been described above by way of the embodiments, the technical scope of the present invention is not limited to the scope described in the above-described embodiments. It is apparent to persons skilled in the art that various alterations or improvements can be made to the above-described embodiments. It is also apparent from the description of the claims that the form to which such alterations or improvements are made can be included in the technical scope of the present invention.

It should be noted that the operations, procedures, steps, stages, and the like of each process performed by an apparatus, system, program, and method shown in the claims, the specification, or the drawings can be realized in any order as long as the order is not indicated by “prior to,” “before,” or the like and as long as the output from a previous process is not used in a later process. Even if the operation flow is described by using phrases such as "first" or "next" for the sake of convenience in the claims, specification, and drawings, it does not necessarily mean that the process must be performed in this order.

### OTHER POSSIBLE ITEMS

### Item 1

A magnetic sensor to identify three components of X, Y, and Z of an incident magnetic field in a three-dimensional Cartesian coordinate system, comprising:

a pair of first magnetoelectric conversion elements positioned in a first quadrant and a third quadrant and a pair of second magnetoelectric conversion elements positioned in a second quadrant and a fourth quadrant, when four quadrants formed of an X-axis, a Y-axis, and an intersection point of the X-axis and the Y-axis are defined, wherein

each of the pair of first magnetoelectric conversion elements has a magnetosensitive axis along a first axis obtained by rotating the X-axis or the Y-axis by 45 degrees, the pair of first magnetoelectric conversion elements are arranged so that positive directions of magnetosensitive axes, each being identical to the magnetosensitive axis, are opposite to each other, and at least one of the pair of first magnetoelectric conversion elements has an electrode pair arranged along the first axis, and

each of the pair of second magnetoelectric conversion elements has a magnetosensitive axis along a second axis which is orthogonal to the first axis, and the pair of second magnetoelectric conversion elements are arranged so that positive directions of magnetosensitive axes, each being identical to the magnetosensitive axis, are opposite to each other.

### Item 2

The magnetic sensor according to item 1, wherein

in an X-Y plane, a distance between a center of gravity of one of the pair of first magnetoelectric conversion elements and a center of gravity of one of the pair of second magnetoelectric conversion elements is shorter than a distance between respective centers of gravity of the pair of first magnetoelectric conversion elements.

### Item 3

The magnetic sensor according to item 1, wherein

in an X-Y plane, each of four magnetoelectric conversion elements included in the pair of first magnetoelectric conversion elements and the pair of second magnetoelectric conversion elements has a rectangular profile with diagonal lines along the first axis and the second axis, and

in the X-Y plane, a first square, which is imaginary, formed by connecting centers of gravity of the four magnetoelectric conversion elements with each other is in a similar relationship with a second square, which is imaginary, circumscribing the four magnetoelectric conversion elements.

### Item 4

The magnetic sensor according to item 3, comprising:

a magnetic flux concentrator arranged to have its outer edge portion inside the second square in the X-Y plane.

### Item 5

The magnetic sensor according to item 3, comprising:

a magnetic flux concentrator arranged to have its outer edge portion outside the first square in the X-Y plane.

### Item 6

The magnetic sensor according to any one of items 1 to 5, wherein

the pair of first magnetoelectric conversion elements are arranged to magnetoelectrically convert a magnetic field of + Hx + Hy and a magnetic field of - Hx - Hy, and

the pair of second magnetoelectric conversion elements are arranged to magnetoelectrically convert a magnetic field of - Hx + Hy and a magnetic field of + Hx - Hy.

### Item 7

A magnetic sensor to identify three components of X, Y, and Z of an incident magnetic field in a three-dimensional Cartesian coordinate system, comprising:

four magnetoelectric conversion elements formed on a silicon substrate; and

a magnetic flux concentrator arranged to overlap with the four magnetoelectric conversion elements, wherein

at least one of the four magnetoelectric conversion elements has an electrode pair arranged along a first axis obtained by rotating an X-axis or a Y-axis by 45 degrees, and

when a signal detected based on an X-component of the incident magnetic field is defined as Hx, a signal detected based on a Y-component is defined as Hy, and a signal detected based on a Z-component is defined as Hz, the four magnetoelectric conversion elements are arranged to detect Hx + Hy + Hz = A, - Hx + Hy + Hz = B, Hx - Hy + Hz = C, and - Hx - Hy + Hz = D.

### Item 8

The magnetic sensor according to item 7, wherein

in an X-Y plane, an area of a portion of the magnetic flux concentrator which overlaps with the four magnetoelectric conversion elements is larger than an area of a portion of the magnetic flux concentrator which does not overlap with the four magnetoelectric conversion elements.

### Item 9

The magnetic sensor according to item 7 or 8, wherein

in an X-Y plane, each of the four magnetoelectric conversion elements has two sets of electrode pairs, and the two sets of electrode pairs are arranged so that a line connecting one electrode pair of the two sets of electrode pairs with each other intersects a line connecting another electrode pair of the two sets of electrode pairs with each other, and are arranged so that an outer edge portion of the magnetic flux concentrator traverses above or below the one electrode pair.

### Item 10

A method to identify three components of X, Y, and Z of an incident magnetic field in a three-dimensional Cartesian coordinate system using four magnetoelectric conversion elements, wherein

at least one of the four magnetoelectric conversion elements has an electrode pair arranged along a first axis obtained by rotating an X-axis or a Y-axis by 45 degrees, the method comprising:

when a signal detected based on an X-component of the incident magnetic field is defined as Hx, a signal detected based on a Y-component is defined as Hy, and a signal detected based on a Z-component is defined as Hz, acquiring values of four magnetic fields of Hx + Hy + Hz = A, - Hx + Hy + Hz = B, Hx - Hy + Hz = C, and - Hx - Hy + Hz = D detected by the four magnetoelectric conversion elements; and

based on the values of the four magnetic fields, identifying the Hx by Hx = {(A + C) - (B + D)}/4, identifying the Hy by Hy = {(A + B) - (C + D)}/4, and identifying the Hz by Hz = (A + B + C + D)/4.

### EXPLANATION OF REFERENCES

10: magnetic field identification device;

100: magnetic sensor;

101, 102, 103, 104: magnetoelectric conversion element;

110: silicon substrate;

120: magnetic flux concentrator;

131, 132, 133, 134: magnetosensitive axis

141-1, 141-2, 141-3, 141-4, 142-1, 142-2, 142-3, 142-4, 143-1, 143-2, 143-3, 143-4, 144-1, 144-2, 144-3, 144-4: electrode;

150: rectangle;

161: first square;

162: second square;

200: signal selection unit;

300: amplifier;

400: ADC;

500: computation processing unit;

D1, D2: distance;

G1, G2, G3, G4: center of gravity;

L-L': line.

What is claimed is:

1. A magnetic sensor to identify three components of X, Y, and Z of an incident magnetic field in a three-dimensional Cartesian coordinate system, comprising:
a pair of first magnetoelectric conversion elements positioned in a first quadrant and a third quadrant and a pair of second magnetoelectric conversion elements positioned in a second quadrant and a fourth quadrant, when four quadrants formed of an X-axis, a Y-axis, and an intersection point of the X-axis and the Y-axis are defined, wherein
each of the pair of first magnetoelectric conversion elements has a magnetosensitive axis along a first axis obtained by rotating the X-axis or the Y-axis by 45 degrees, the pair of first magnetoelectric conversion elements are arranged so that positive directions of magnetosensitive axes, each being identical to the magnetosensitive axis, are opposite to each other, and at least one of the pair of first magnetoelectric conversion elements has an electrode pair arranged along the first axis,
each of the pair of second magnetoelectric conversion elements has a magnetosensitive axis along a second axis which is orthogonal to the first axis, and the pair of second magnetoelectric conversion elements are arranged so that positive directions of magnetosensitive axes, each being identical to the magnetosensitive axis, are opposite to each other, and
in an X-Y plane, an area of an imaginary rectangle formed by connecting with each other a pair of points that are proximate to each other in the pair of first magnetoelectric conversion elements and a pair of points that are proximate to each other in the pair of second magnetoelectric conversion elements is smaller than an area of each of four magnetoelectric conversion elements included in the pair of first magnetoelectric conversion elements and the pair of second magnetoelectric conversion elements.

2. The magnetic sensor according to claim 1, wherein
in an X-Y plane, a distance between a center of gravity of one of the pair of first magnetoelectric conversion elements and a center of gravity of one of the pair of second magnetoelectric conversion elements is shorter than a distance between respective centers of gravity of the pair of first magnetoelectric conversion elements.

3. The magnetic sensor according to claim 1, wherein
in an X-Y plane, each of the four magnetoelectric conversion elements has a rectangular profile with diagonal lines along the first axis and the second axis, and
in the X-Y plane, a first square, which is imaginary, formed by connecting centers of gravity of the four magnetoelectric conversion elements with each other is in a similar relationship with a second square, which is imaginary, circumscribing the four magnetoelectric conversion elements.

4. The magnetic sensor according to claim 3, comprising:
a magnetic flux concentrator arranged to have its outer edge portion inside the second square in the X-Y plane.

5. The magnetic sensor according to claim 3, comprising:
a magnetic flux concentrator arranged to have its outer edge portion outside the first square in the X-Y plane.

6. The magnetic sensor according to claim 1, wherein
the pair of first magnetoelectric conversion elements are arranged to magnetoelectrically convert a magnetic field of + Hx + Hy and a magnetic field of - Hx - Hy, and
the pair of second magnetoelectric conversion elements are arranged to magnetoelectrically convert a magnetic field of - Hx + Hy and a magnetic field of + Hx - Hy.

7. The magnetic sensor according to claim 2, wherein
the pair of first magnetoelectric conversion elements are arranged to magnetoelectrically convert a magnetic field of + Hx + Hy and a magnetic field of - Hx - Hy, and
the pair of second magnetoelectric conversion elements are arranged to magnetoelectrically convert a magnetic field of - Hx + Hy and a magnetic field of + Hx - Hy.

8. The magnetic sensor according to claim 3, wherein
the pair of first magnetoelectric conversion elements are arranged to magnetoelectrically convert a magnetic field of + Hx + Hy and a magnetic field of - Hx - Hy, and
the pair of second magnetoelectric conversion elements are arranged to magnetoelectrically convert a magnetic field of - Hx + Hy and a magnetic field of + Hx - Hy.

9. The magnetic sensor according to claim 4, wherein
the pair of first magnetoelectric conversion elements are arranged to magnetoelectrically convert a magnetic field of + Hx + Hy and a magnetic field of - Hx - Hy, and
the pair of second magnetoelectric conversion elements are arranged to magnetoelectrically convert a magnetic field of - Hx + Hy and a magnetic field of + Hx - Hy.

10. The magnetic sensor according to claim 5, wherein
the pair of first magnetoelectric conversion elements are arranged to magnetoelectrically convert a magnetic field of + Hx + Hy and a magnetic field of - Hx - Hy, and
the pair of second magnetoelectric conversion elements are arranged to magnetoelectrically convert a magnetic field of - Hx + Hy and a magnetic field of + Hx - Hy.

11. A magnetic sensor to identify three components of X, Y, and Z of an incident magnetic field in a three-dimensional Cartesian coordinate system, comprising:
four magnetoelectric conversion elements formed on a silicon substrate; and
a magnetic flux concentrator arranged to overlap with the four magnetoelectric conversion elements, wherein
at least one of the four magnetoelectric conversion elements has an electrode pair arranged along a first axis obtained by rotating an X-axis or a Y-axis by 45 degrees,
in an X-Y plane, an area of a portion of the magnetic flux concentrator which overlaps with the four magnetoelectric conversion elements is larger than an area of a portion of the magnetic flux concentrator which does not overlap with the four magnetoelectric conversion elements, and
when a signal detected based on an X-component of the incident magnetic field is defined as Hx, a signal detected based on a Y-component is defined as Hy, and a signal detected based on a Z-component is defined as Hz, the four magnetoelectric conversion elements are arranged to detect Hx + Hy + Hz = A, - Hx + Hy + Hz = B, Hx - Hy + Hz = C, and - Hx - Hy + Hz = D.

12. The magnetic sensor according to claim 11, wherein
in an X-Y plane, each of the four magnetoelectric conversion elements has two sets of electrode pairs, and the two sets of electrode pairs are arranged so that a line connecting one electrode pair of the two sets of electrode pairs with each other intersects a line connecting another electrode pair of the two sets of electrode pairs with each other, and are arranged so that an outer edge portion of the magnetic flux concentrator traverses above or below the one electrode pair.

13. A magnetic field identification method to identify three components of X, Y, and Z of an incident magnetic field in a three-dimensional Cartesian coordinate system using four magnetoelectric conversion elements, wherein
at least one of the four magnetoelectric conversion elements has an electrode pair arranged along a first axis obtained by rotating an X-axis or a Y-axis by 45 degrees,
a magnetic flux concentrator is arranged to overlap with the four magnetoelectric conversion elements, and
in an X-Y plane, an area of a portion of the magnetic flux concentrator which overlaps with the four magnetoelectric conversion elements is larger than an area of a portion of the magnetic flux concentrator which does not overlap with the four magnetoelectric conversion elements, the method comprising:
when a signal detected based on an X-component of the incident magnetic field is defined as Hx, a signal detected based on a Y-component is defined as Hy, and a signal detected based on a Z-component is defined as Hz, acquiring values of four magnetic fields of Hx + Hy + Hz = A, - Hx + Hy + Hz = B, Hx - Hy + Hz = C, and - Hx - Hy + Hz = D detected by the four magnetoelectric conversion elements; and
based on the values of the four magnetic fields, identifying the Hx by Hx = {(A + C) - (B + D)}/4, identifying the Hy by Hy = {(A + B) - (C + D)}/4, and identifying the Hz by Hz = (A + B + C + D)/4.
